(19) United States
(12) Patent Application Publication
(10) Pub. No.: US 2009/0004769 A1
(43) Pub. Date: Jan. 1, 2009

(54) METHOD FOR MANUFACTURING IMAGE SENSOR

(75) Inventors: Young Seok JEONG, Busan (KR); Han Choon LEE, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/145,438

(22) Filed: Jun. 24, 2008

(30) Foreign Application Priority Data
Jun. 25, 2007 (KR) 10-2007-0062164

(51) Int. Cl. H01L 31/0216; H01L 31/18

(52) U.S. Cl. 438/69; 438/98; 257/E31.119; 257/E21.536

(57) ABSTRACT

A method for manufacturing an image sensor is disclosed. The manufacturing method includes forming a unit pixel including a photodiode and a gate on a semiconductor substrate, forming an interlayer insulating layer on the semiconductor substrate including the unit pixel, planarizing the interlayer insulating layer, forming a protection layer with SiH₄ on the interlayer insulating layer, and planarizing the protection layer.

### CROSS-REFERENCE TO A RELATED APPLICATION

This application claims the benefit of the Korean Patent Application No. 10-2007-0062164, filed on 25 Jun. 2007, which is hereby incorporated by reference as if fully set forth herein.

### BACKGROUND

1. Field of the Invention

The present invention relates to a semiconductor device, and more particularly, to a method for manufacturing an image sensor.

2. Discussion of the Related Art

A complementary metal-oxide semiconductor (CMOS) image sensor, which is one example of an image sensor implementation, uses a CMOS technology that includes both a control circuit and a signal processing circuit as peripheral circuits.

In a typical implementation, a CMOS image sensor includes a plurality of photodiodes and MOS transistors in accordance with the number of pixels desired. In operation, the sensor sequentially detects electric signals output from each unit pixel by switching, thereby generating an image.

In such a CMOS image sensor, photosensitivity, which is an important factor determining the performance of the CMOS image sensor, is influenced by a phenomenon known as “dark current.”

Dark current is typically generated by various defects in the semiconductor device, such as a line defect and a point defect, which can be scattered about between a surface of a semiconductor substrate and an oxide layer or by a dangling bond. Such defects give rise to dark current, and consequently deteriorate the performance of the image sensor.

### SUMMARY OF EXAMPLE EMBODIMENTS

In general, example embodiments of the present invention relate to a method for manufacturing an image sensor. In particular, proposed embodiments seek to provide an image sensor that has improved photosensitivity. In addition, disclosed embodiments provide an image sensor that is capable of improving alignment recognition in the process of lithography.

In one example embodiment a method for manufacturing an image sensor comprises forming a unit pixel including a photodiode and a gate on a semiconductor substrate. An interlayer insulating layer is formed on the semiconductor substrate, including the unit pixel. The interlayer insulating layer is planarized so as to form a protection layer with, for example, SiH₄ on the interlayer insulating layer. The protection layer can be planarized.

In another example embodiment, a method for manufacturing an image sensor includes the steps of forming a pixel area and a scribe line on a semiconductor substrate. A unit pixel, including a photodiode and a gate, is formed on the pixel area. An interlayer insulating layer is formed on the pixel area and the scribe line, and a protection layer with, for example SiH₄, is formed on the interlayer insulating layer. Contact plugs are formed on the pixel area by etching the protection layer and the interlayer insulating layer, and forming alignment keys on the scribe line.

In general, disclosed embodiments reduce the occurrence of dark currents by providing a protection layer on the interlayer insulating layer. This results in an image sensor that has improved photosensitivity. In addition, uniform thickness of the interlayer insulating layer and the protection layer help the contact plug and the alignment key have uniform profiles, thereby enhancing alignment recognition during the lithography process.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate example embodiment(s) of the invention and along with the description serve to explain principles of the invention. In the drawings:

FIG. 1 through FIG. 5 are sectional views illustrating manufacturing processes for an image sensor, according to one example embodiment;

FIG. 6 is a graph illustrating the resistance property of a contact plug formed in accordance with the configuration of the contact hole of FIG. 6;

FIG. 7 is a graph illustrating the dark signal property in accordance with the thickness of the protection layer, according to the disclosed example embodiments; and

FIG. 8 is a graph illustrating the white line property in accordance with the thickness of the protection layer, according to the disclosed example embodiments.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In general, embodiments of the present invention are directed to methods for manufacturing an image sensor that result in an image sensor having improved performance characteristics.

In the following description, it will be appreciated that when an element is explained as being “on” or “over” another element, the element can be referred to as being formed on the another element directly or through the medium of another layer, that is, indirectly.

In addition, in the drawings, each layer may be exaggerated in thickness and size, or certain elements are briefly illustrated or even omitted for convenient explanation. Therefore, the drawings do not reflect the actual size of the elements.

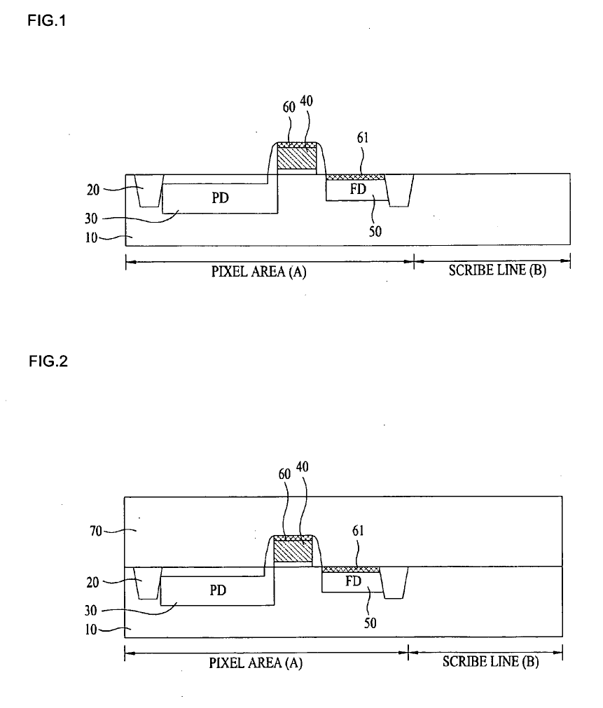

Referring to FIG. 1 through FIG. 5, one example of a method for manufacturing an image sensor is shown.

First, as shown in FIG. 1, a semiconductor substrate 10 comprises a pixel area A and a scribe line B.

The pixel area A refers to a part of the semiconductor substrate 10 on which an element is formed. The scribe line B refers to a part on which alignment keys necessary for lithography are formed.

The pixel area A is divided into an active region and a field region, and an element separation layer 20 is formed to define a unit pixel on the pixel area A.

Additionally, the unit pixel is formed on the pixel area A, including a photodiode 30 for detecting light and a gate 40 of a transistor circuit.

Although not shown, the transistor circuit could comprise, for example, a transfer transistor, a reset transistor, a drive transistor and a select transistor.

In the illustrated embodiment, gate 40 includes a gate dielectric layer and a gate electrode. For example, the gate 40 may be fabricated by forming an oxide layer and a polysilicon layer on the pixel area A and then forming a gate oxide layer and the gate electrode by etching. Here, the gate 40 may be a gate of the transfer transistor adjoining the photodiode 30.

In the illustrated embodiment, the photodiode 30 is formed next to one side of the gate 40, while a floating diffusion region 50 is formed next to the other side of the gate 40.

The gate 40 and the floating diffusion region 50 may include silicide layers 60 and 61 thereon, respectively. The silicide layers 60 and 61 are provided to relieve contact resistance applied to the gate 40 and the floating diffusion region 50. In the illustrated example, the silicide layers 60 and 61 may be formed by depositing conductive metal such as cobalt, nickel and titanium on the gate 40 and the floating diffusion region 50 and performing thermal processing.

As is shown in FIG. 2, an interlayer insulating layer 70 is then formed on the pixel area A and the scribe line B.

The interlayer insulating layer 70 provides insulation between the transistor and electric wires, and may be implemented, for example, by a Pre Metal Dielectric (PMD) layer or an Inter Layer Dielectric (ILD) layer. By way of example, the interlayer insulating layer 70 may comprise Phosphorus Silicate Glass (PSG), Boro-Phosphorus Silicate Glass (BPSG) and PE-TEOS structured in single or multiple layers. In one example, the interlayer insulating layer 70 may be formed by depositing the BPSG layer through a Chemical Vapor Deposition (CVD) process and then planarizing the deposited layer through a Chemical Mechanical Polishing (CMP) process. The thickness of the interlayer insulating layer 70 may be within a range of approximately 2000-5000 Å.

As is shown in FIG. 3, a protection layer is formed on the interlayer insulating layer 70 to protect a surface of the interlayer insulating layer 70. In one example, the protection layer 80 may comprise SiH₄. For example, the protection layer 80 may be fabricated by depositing SiH₄ through the CVD process at temperature of approximately 200-500° C. In addition, the protection layer 80 may be in a thickness of about 1000-5000 Å.

In disclosed embodiments, H₂ is generated during fabrication of the protection layer 80. By penetrating into the semiconductor substrate 10, the H₂ converts the structure of a dangling bond formed on the semiconductor substrate 10 into a Si—H structure. The dangling bond is incurred as the bonding of the substrate surface is damaged by repetitive etching performed to form elements on the semiconductor substrate. In addition, since the dangling bond is apt to thermally generate electric charges even without optical input, especially where a number of dangling bonds exist, a dark current can be generated. Accordingly, the image sensor may abnormally operate, that is, react as if it received light even when no light is present.

Therefore, by injecting the H₂ in the semiconductor substrate 10, the dangling bonds can be reduced and consequently generation of the dark current can be prevented.

In disclosed embodiments, the CMP process is performed to planarize the protection layer 80. For example, the protection layer 80 may reduced to a thickness of approximately 1500-2500 Å after the CMP process.

If the thickness of the protection layer 80 is less than about 1500 Å, the interlayer insulating layer 70 disposed under the protection layer 80 may also be polished during the CMP process, thereby exposing the BPSG layer of the interlayer insulating layer 70.

Since the protection layer 80 and the interlayer insulating layer 70 are formed of different materials, and therefore have different abrasiveness, the interlayer insulating layer 70 disposed under the protection layer 80 can be exposed during polishing of the protection layer 80. In this case, an erosion or dishing phenomenon may occur during post-processing, that is, during formation of a contact plug or the alignment key, thereby causing misalignment during the lithography process.

In this embodiment, since the protection layer 80 has the thickness of 1500˜2500 Å, undesired polishing or exposure of the interlayer insulating layer 70 can be prevented. As a result, the contact plug and the alignment key can be formed normally.

As is shown in FIG. 4, a photoresist pattern 200 is formed on the semiconductor substrate 10 which includes the protection layer 80. In the illustrated embodiment, the photoresist pattern 200 is provided to expose the gate 40 and the floating diffusion region 50 formed on the pixel area A by selectively removing the protection layer 80 at locations corresponding to the gate 40 and the floating diffusion region 50. In addition, the photoresist pattern 200 can be used to selectively remove the protection layer 80 so as to form the alignment key on the scribe line B.

With the photoresist pattern 200 functioning as a mask, the protection layer 80 and the interlayer insulating layer 70 are etched, thereby forming contact holes 91 and 93 on the pixel area A and a mark hole 95 on the scribe line B.

The mark hole 95 can be formed larger than the contact holes 91 and 93. Alternatively, the mark hole 95 and the contact holes 91 and 93 may be formed to be approximately the same size.

Here, due to the 1500˜2500 Å thickness of the protection layer 80, bowing of the contact holes 91 and 93 and the mark hole 95 can be prevented.

The bowing denotes an uneven etching profile of the contact hole, which is caused when the etching is incompletely performed up to a lower part of the contact hole due to excessive thickness of the interlayer insulating layer and the protection layer. As discussed, the protection layer 80 of the disclosed example embodiment has a proper thickness and therefore, the contact holes 91 and 93 and the mark hole 95 can have uniform etching profiles.

As shown in FIG. 5, the photoresist pattern 200 is removed. The contact plugs 100 and 110 and the alignment key 120 are then formed in the contact holes 91 and 93 and the mark holes 95 respectively.

In one embodiment, the contact plugs 100 and 110 and the alignment key 120 can be formed by filling the semiconductor substrate 10 including the contact holes 91 and 93 and the mark hole 95 with metal.

Regarding the CMP of the metal layer, the etching is performed up to the protection layer 80.

Because the CMP for formation of the contact plugs and the alignment key is finished at the protection layer 80 having the uniform thickness, erosion and dishing of the contact plugs and the alignment key can also be minimized.

Since the alignment key 120 thus can be formed to have a uniform profile, the alignment recognition in the following lithography can be improved.

As is shown in Table 1, the etching profile of the contact hole according to the thickness of the protection layer, the resistant property, the dark current property, and the white line property are compared.

TABLE 1

| Applied process | | | |
|---|---|---|---|
| Protection layer | | | |
| when contact is | Class | Substrate no. | Thickness |
| established | Reference group | #01~05 | 1000 Å |
| | Group 1 (Split 1) | #06~10 | 1500 Å |
| | Group 2 (Split 2) | #11~15 | 2000 Å |
| | Group 3 (Split 3) | #16~20 | 2500 Å |

Table 1 denotes the thickness of the protection layer formed on the interlayer insulating layer according to one example embodiment. The thickness of the reference group of the protection layer is 1000 Å, group 1 is 1500 Å, group 2 is 2500 Å, and group 3 is 2500 Å.

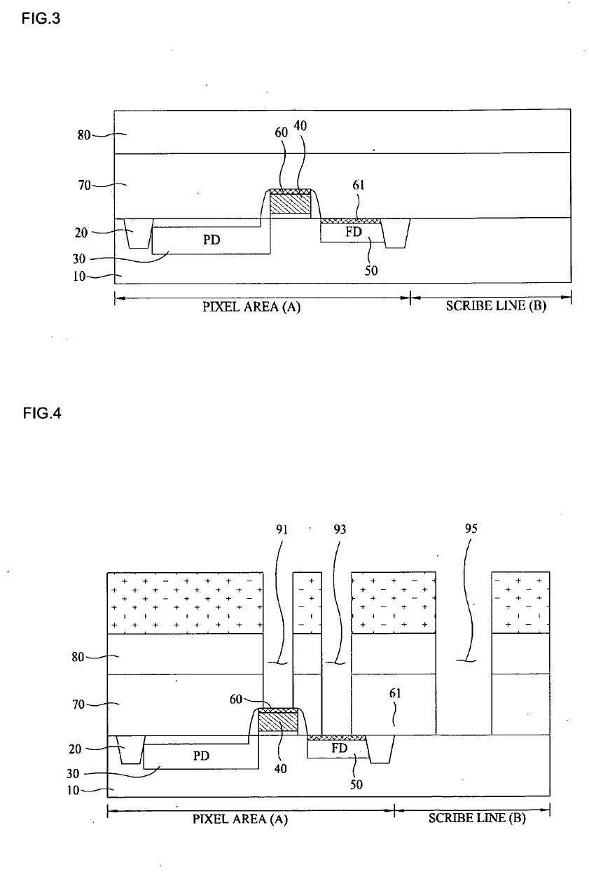

FIG. 6 is a graph illustrating the resistance property of the contact plug according to the classification in Table 1. The X-axis of the graph denotes resistance values in Ohms, while the Y-axis denotes classified groups.

As shown in FIG. 6, the resistance value of the substrates #02 and #03 of the reference group is about 12 Ohms, the substrates #07, #08 and #09 of the group 1 is about 12.5 Ohms, the substrates #12, #13 and #14 of the group 2 is about 13 Ohms, and the substrates #17, #18 and #19 of the group 3 is about 13.5 Ohms.

Thus, the resistance of the contact plugs increases as the protection layer thickness increases, according to the critical dimension by the bowing.

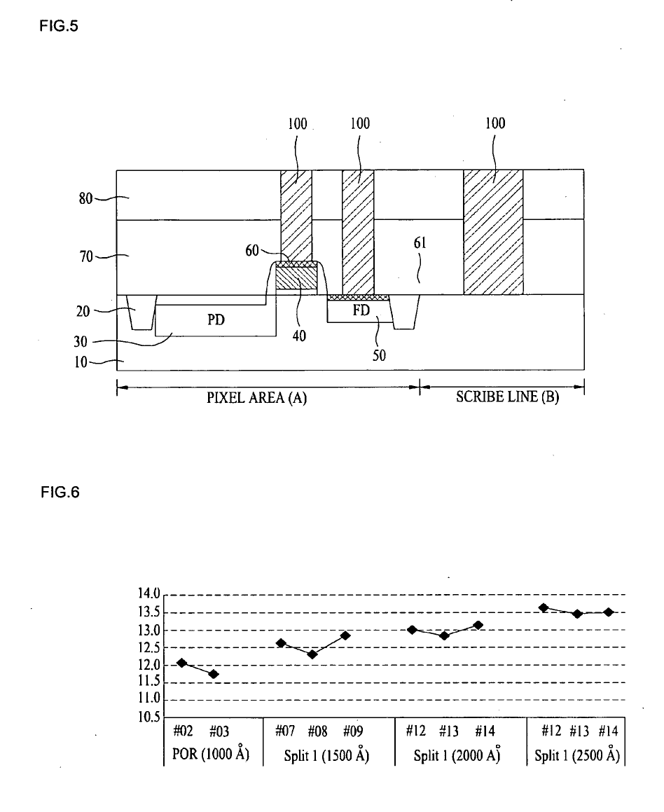

FIG. 7 is a graph illustrating the dark current (DRK_SIGNAL) property according to the classification in Table 1, wherein the X-axis denotes substrate numbers of the classified groups and the Y-axis denotes the number of the dark current generated.

As shown in FIG. 7, a maximum of 50 dark currents occurred in the reference group, a maximum of 30 dark currents occurred in group 1, and less than 10 dark currents occurred both in groups 2 and 3.

Thus, generation of the dark currents is decreased according to an increase of the protection layer thickness.

This is because H₂ penetrates the semiconductor substrate as SiH₄ used for the protection layer is deposited, thereby changing the structure of the dangling bond. Therefore, the dark current by the dangling bond can be prevented.

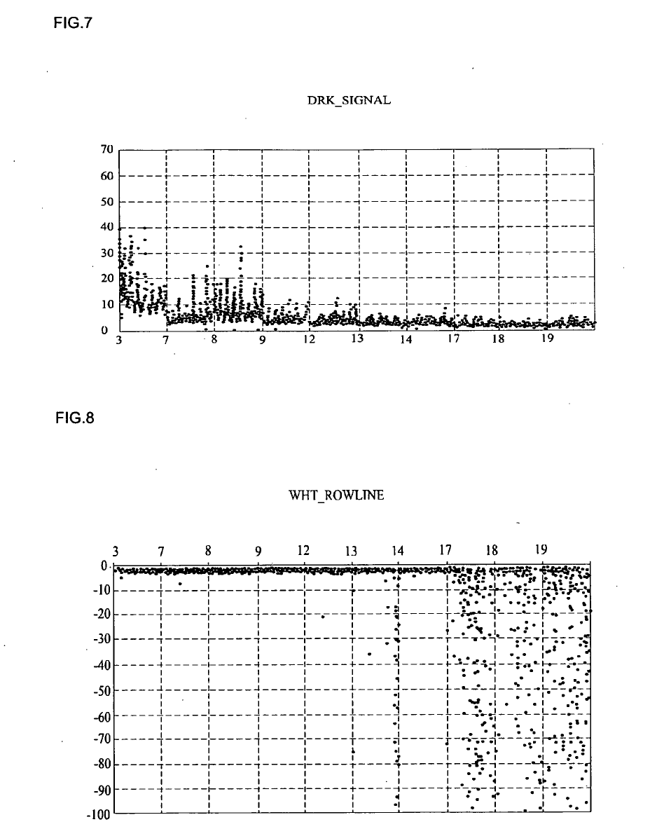

FIG. 8 is a graph illustrating the white line property (WHT-ROWLINE), wherein the X-axis denotes the substrate number and the Y-axis denotes the number of white lines generated.

As shown in FIG. 8, the rate of white lines in the reference group and group 1 is under −5. In group 2, the white line generated only in the substrate #14. In group 3, the rate of white line abruptly increased.

From the above, it can be understood that the white line is generated from when the protection layer thickness is above about 2000 Å.

This is because the bowing occurs only when the protection layer thickness is above about 2000 Å as aforementioned.

As can be appreciated from the above, in order to improve recognition of the alignment key and reduce the dark current and the white line, which are essential factors for improvement of the yield, the protection layer preferably has the thickness within a range of about 1500-2000 Å.

As will be appreciated from the foregoing description, embodiments of the present invention reduce the occurrence of dark currents by providing a protection layer on an interlayer insulating layer. This results in an image sensor that has improved photosensitivity.

In addition, uniform thickness of the interlayer insulating layer and the protection layer help the contact plug and the alignment key have uniform profiles, thereby enhancing alignment recognition during the lithography process.

Although example embodiments of the present invention have been shown and described, changes might be made in these example embodiments. The scope of the invention is therefore defined in the following claims and their equivalents.

What is claimed is:

1. A method for manufacturing an image sensor, comprising the steps of:
forming a unit pixel including a photodiode and a gate on a semiconductor substrate;
forming an interlayer insulating layer on the semiconductor substrate including the unit pixel;
planarizing the interlayer insulating layer;
forming a protection layer with SiH₄ on the interlayer insulating layer; and
planarizing the protection layer.

2. The manufacturing method according to claim 1, wherein the protection layer is deposited at approximately 200˜500° C. by chemical vapor deposition (CVD).

3. The manufacturing method according to claim 1, wherein the protection layer has a thickness of approximately 1500˜2500 Å.

4. The manufacturing method according to claim 1, wherein the interlayer insulating layer comprises boro-phosphorus silicate glass (BPSG).

5. The manufacturing method according to claim 1, further comprising the steps of:
forming contact holes on the protection layer and the interlayer insulating layer after planarization of the protection layer; and
forming a contact plug by filling the contact holes with metal.

6. The manufacturing method according to claim 1, wherein the photodiode is formed on a surface of the semiconductor substrate next to one side of the gate while a floating diffusion region is formed next to the other side of the gate.

7. The manufacturing method according to claim 6, wherein the gate and the floating diffusion region each include a silicide layer.

8. The manufacturing method according to claim 7, wherein the silicide layer is formed from metal by thermal processing.

9. A method for manufacturing an image sensor, comprising the steps of:
forming a pixel area and a scribe line on a semiconductor substrate;
forming a unit pixel including a photodiode and a gate on the pixel area;
forming an interlayer insulating layer on the pixel area and the scribe line;
forming a protection layer with SiH₄ on the interlayer insulating layer; and
forming contact plugs on the pixel area by etching the protection layer and the interlayer insulating layer, and forming alignment keys on the scribe line.

10. The manufacturing method according to claim 9, wherein the interlayer insulating layer comprises boro-phosphorus silicate glass (BPSG).

11. The manufacturing method according to claim 9, wherein the protection layer is deposited at approximately 200˜500° C. by chemical vapor deposition (CVD).

12. The manufacturing method according to claim 9, wherein the protection layer has a thickness of approximately 1500˜2500 Å.

13. The manufacturing method according to claim 9, wherein the contact plug and the alignment key are approximately the same size.

14. The manufacturing method according to claim 9, wherein the photodiode is formed on a surface of the semiconductor substrate next to one side of the gate while the floating diffusion region is formed next to the other side of the gate.

15. The manufacturing method according to claim 14, wherein the gate and the floating diffusion region each include a silicide layer.

16. The manufacturing method according to claim 15, wherein the silicide layer is formed from metal by thermal processing.
